(19) United States
(12) Patent Application Publication
(10) Pub. No.: US 2006/0205143 A1
(43) Pub. Date: Sep. 14, 2006

(54) DRAM with high K dielectric storage capacitor and method of making the same

(76) Inventor: Shrinivas Govindarajan, Niskayuna, NY (US)

Correspondence Address: SLATER & MATSIL LLP, 17950 PRESTON ROAD, SUITE 1000, DALLAS, TX, 75252, US

(21) Appl. No.: 11/433,938

(22) Filed: May 15, 2006

Related U.S. Application Data
(62) Division of application No. 11/031,691, filed on Jan. 7, 2005.

(51) Int. Cl. H01L 21/8242

(52) U.S. Cl. 438/240

(57) ABSTRACT

A memory cell is fabricated by forming a first capacitor electrode including silicon. A metal layer is formed in physical contact with the first capacitor electrode. The metal layer is formed from a material having a high affinity for oxygen and a melting point above about 1000° C. A layer of high K dielectric material is formed in physical contact with the metal layer. The high K dielectric material has a dielectric constant greater than about 5. A conductive layer is formed over the high K dielectric material layer. An interface between the high K dielectric layer and the metal layer/silicon body is modified by performing an annealing step. A transistor is also formed to be electrically coupled to one of the conductive layer or the first capacitor electrode.

This application is a divisional of co-pending application Ser. No. 11/031,691, entitled “DRAM with High K Dielectric Storage Capacitor and Method of Making the Same,” filed Jan. 7, 2005, which application is incorporated herein by reference.

### CROSS-REFERENCE TO RELATED APPLICATIONS

This application is related to the following co-pending applications, both of which are incorporated herein by reference: application Ser. No. 11/031,716, filed Jan. 7, 2005, and entitled “High Dielectric Constant Materials” (Attorney Docket 2004P54456) and application Ser. No. 11/031,596, filed Jan. 7, 2005, and entitled “Method to Control Interfacial Properties for Capacitors Using a Metal Layer” (Attorney Docket 2004P54458).

### TECHNICAL FIELD

The present invention relates generally to semiconductor devices and methods, and more particularly to a DRAM with a high K dielectric storage capacitor and a method of making the same.

### BACKGROUND

A dynamic random access memory (DRAM) is a memory device that can be used to store information. DRAMs are favored in some applications because they are relatively inexpensive to fabricate in very high densities. Each DRAM cell typically includes two elements, namely a storage capacitor and an access transistor. Data can be stored into and read out of the storage capacitor by passing charge through the access transistor and into the capacitor. The capacitance, or amount of charge held by the capacitor per applied voltage, is measured in farads and depends upon the area of the plates, the distance between them, and the dielectric value of the insulator, as examples. One goal of DRAM cell design is to maximize the capacitance of the storage capacitor.

Another goal for DRAM design is to minimize the leakage of charge from the storage capacitor. In any practical device, charge will slowly leak from the capacitor. As a result, the memory cell must be periodically refreshed. Lowering the leakage from the cell can lead to one or more advantages. The time between periodic refreshes can be increased thereby lowering power consumed by the device and increasing the amount of time that the device is available for other functions. Another possibility is to lower the operating voltages so that a smaller amount of charge can be stored in the cell. Finally, the capacitor can be made smaller without lowering the capacitance if the dielectric constant of the dielectric material is commensurately increased.

For DRAM capacitors, some key requirements for sub-70 nm technologies are low leakage current, low Equivalent Oxide Thickness (EOT), minimization of polysilicon depletion, adequate band offsets (for the dielectric), and thermal stability during subsequent processing. To achieve these requirements, the idea of using MIS (metal-insulator-silicon) or MIM (metal-insulator-metal) capacitors is known. A key challenge is to optimize the various interface properties and to use dielectrics with high capacitance.

A number of high-dielectric constant materials are known for capacitors. Examples of high dielectric constant materials that have been proposed as capacitor dielectrics are tantalum pentoxide, titanium oxide, barium strontium titanate, and titanium oxide. To get a dielectric constant that is greater than 10, the prior art has focused on materials based on the HfᵤAlᵥSi_{w}OₓN_{y} or LaᵤAlᵥSi_{w}OₓN_{y} systems (where the subscripts refer to the atomic proportions of each element, each varying between a 0 to 100% such that the sum of the subscripts totals about 100%, excluding contaminants such as Cl, H, C). These materials are limited to a maximum dielectric constant of around 30.

### SUMMARY OF THE INVENTION

These and other problems are generally solved or circumvented, and technical advantages are generally achieved, by preferred embodiments of the present invention, which discloses a DRAM with a high K dielectric storage capacitor and a method of making the same.

In accordance with a preferred embodiment of the present invention, a dynamic random access memory cell includes a transistor formed in a semiconductor body. A capacitor is coupled to the transistor and includes a first capacitor plate formed from silicon. A metal layer is adjacent to and electrically coupled to the first capacitor plate. A capacitor dielectric layer is adjacent to the metal layer. The capacitor dielectric layer comprises material having a dielectric constant greater than about 5 (or 10 or 20). A second capacitor plate is adjacent to the capacitor dielectric. The capacitor can be either a trench capacitor or a stacked capacitor.

In another embodiment, a method of fabricating a memory cell includes forming a first capacitor electrode. A metal layer is formed in physical contact with the first capacitor electrode. The metal layer can be formed from a material having a high affinity for oxygen and a melting point above about 1000° C. A layer of high K dielectric material is formed in physical contact with the metal layer. The high K dielectric material has a dielectric constant greater than about 5. A conductive layer is formed over the high K dielectric material layer. An interface between the high K dielectric layer and the metal layer/silicon body can be modified by performing an annealing step (e.g., either RTA or furnace). A transistor within the silicon body can be electrically coupled to one of the conductive layer or the first capacitor electrode.

Various embodiments of the invention are based upon at least two core concepts. The first concept is to use an oxygen/nitrogen gettering layer (sacrificial in nature since it may be partially or completely converted to a new phase) as a means of modifying the interface between a dielectric layer and a semiconductor layer. In the second concept, a high K layer based on HfᵤTiᵥTa_{w}OₓN_{y} mixed films or nanolaminates can be used to achieve dielectric constants above 25 to 35.

Metals, such as titanium, form a solid solution with oxygen and are, therefore, very effective as gettering layers. Furthermore, formation of a conductive silicide layer at the interface would be very useful for creating MIM capacitors. Alternatively, if processing conditions are selected such that a silicate layer forms, the uniformity and higher dielectric constant of such a layer would help to minimize the interfacial contribution to EOT. The segregation of oxygen can be tailored (through temperature, time, and partial pressure control) such that a pure silicide is in contact with the silicon substrate and the silicate/oxide is formed above the silicide layer.

The high K layer is based on TiO₂, which has a dielectric constant in the range of 80. However, TiO₂ by itself will not be adequate due to the low band gap (˜3.05 eV) and the negligible conduction band offset to Si (close to 0 eV). Combining TiO₂ with higher band gap materials (even though they may have lower dielectric constant) is one possibility. Some possibilities include HfO₂, Ta₂O₅, SrO (dielectric constant for SrTiO₃ is close to 100) and certain dielectric nitrides (e.g., Hf₃N₄, ZrN₄). The two broad categories of dielectrics proposed here are either mixed oxides/nitrides based on Ti and Ta (Hf—Ti—Ta—O—N) or nanolaminates of the same (using combinations or subsets of TiO₂, HfO₂, Hf₃N₄, Ta₂O₅ . . . ). The mixed films are deposited by ALD of the individual components (e.g. HfO₂ using TEMAHf and O₃ or H₂O, TiO₂ using either TiCl₄ or Ti(OEt)₄ and O₃ or H₂O, Ta₂O₅ using TBTEMT and O₃ or H₂O, Hf₃N₄ using TEMAHf with NH₃, etc.) with the thickness of each layer adjusted to ensure intimate film mixing. The nanolaminate structures are formed by using thicker sub-layers of each component film. The nanolaminate structures provide a key benefit in terms of preventing grain growth and controlling the crystallization behavior of the dielectric film.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1a is a cross-sectional view of a first embodiment trench memory cell;

FIG. 1b is a schematic diagram of the cell of FIG. 1a (and FIGS. 2 and 9);

FIG. 2 is a second embodiment trench memory cell;

FIGS. 3-8 illustrate various stages of a process flow to fabricate a trench memory cell; and

FIG. 9 is a stacked capacitor memory cell that can utilize aspects of the invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a DRAM cell. The invention may also be applied, however, to other devices that include capacitors. For example, any integrated circuit that uses a capacitor can benefit from the teachings of the present invention.

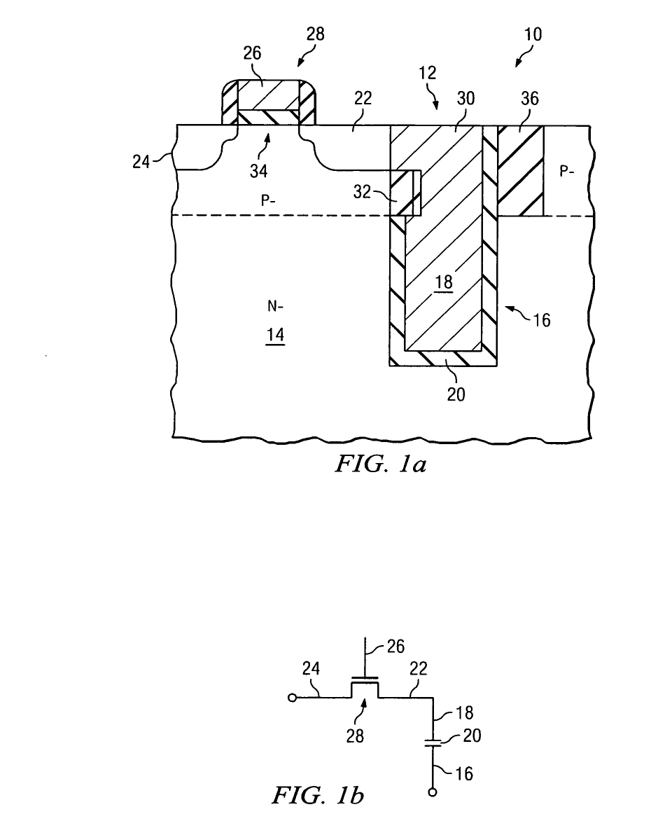

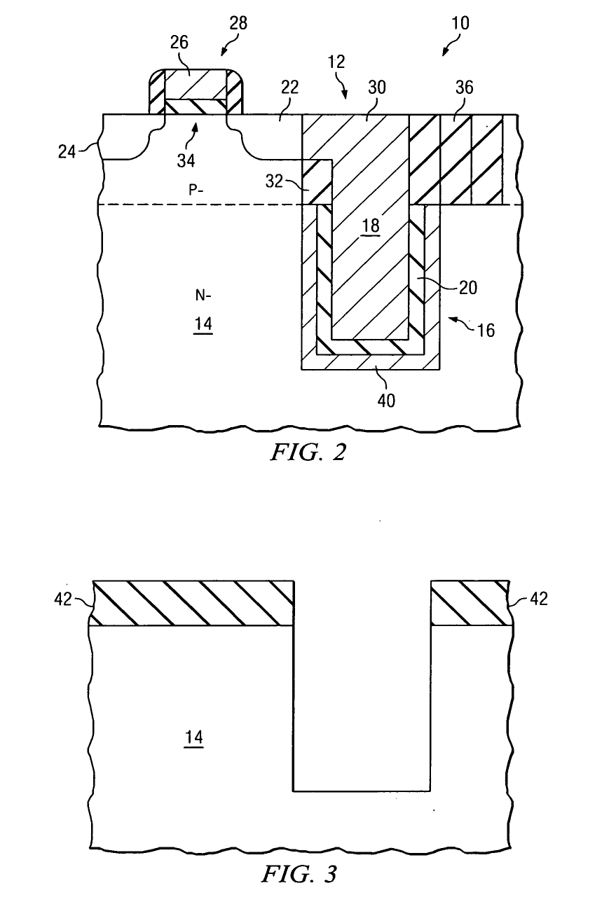

FIG. 1a shows a first example of a DRAM cell 10 that can utilize concepts of the present invention. FIG. 1b shows a schematic diagram of the cell of FIG. 1a. The embodiment of FIG. 1a includes a trench capacitor 12, which is formed in the semiconductor body 14. The capacitor includes two plates and an intervening dielectric layer. In the illustrated example, the first plate is formed from the substrate region 16 and the second plate is conductive material 18 within the trench. Dielectric layer 20 is formed along the sidewalls and bottom of the trench between the two capacitor plates. In the illustrated embodiment, the capacitor electrode 16 is formed from a buried n-doped region and is common to a number of capacitors.

As shown in the schematic diagram as well as the cross-section, the storage plate 18 is electrically coupled to the source/drain region 22 of access transistor 28. In this embodiment, a conductive strap 30 formed in an upper portion of the trench electrically couples the storage plate 18 to the doped region 22. Isolation collar 32 is provided to electrically isolate the capacitor electrode 16 from the doped region 22. Shallow trench isolation region 36 electrically isolates the trench capacitor 12 from adjacent any devices (e.g., the storage cell of an adjacent memory).

The access transistor 28 includes source/drain regions 22 and 24 formed in the semiconductor body 14. The source/drain region 24 is typically coupled to a bit line (not shown). The gate electrode 26 overlies a channel 34 so as to control the conductivity of the channel and thereby provide access to the storage cell 12. The gate electrode 26 is typically coupled to a word line (not shown).

In one aspect, the present invention focuses on the interface between the buried plate 16 and the capacitor dielectric 20 and the electrode 18. In particular, it is desirable to control the interface between the silicon of semiconductor body 14 (which is prone to forming a native oxide) and the electrode 18 (which may comprise metal) or dielectric 20 in order to achieve EOT (effective oxide thickness) less than 1 nm. Use of a pure metal layer in electrode 18 in the vicinity of the interface will help to minimize the interfacial layer contribution to EOT. Combining this metal electrode with a suitable dielectric layer 20 with high dielectric constant will help minimize EOT. As will be discussed below, one embodiment of this invention proposes the use of a silicon substrate followed by pure metal flash layer (e.g., Ti, Ru, Hf, and/or Ta) and various high K mixed films or nanolaminate dielectric systems.

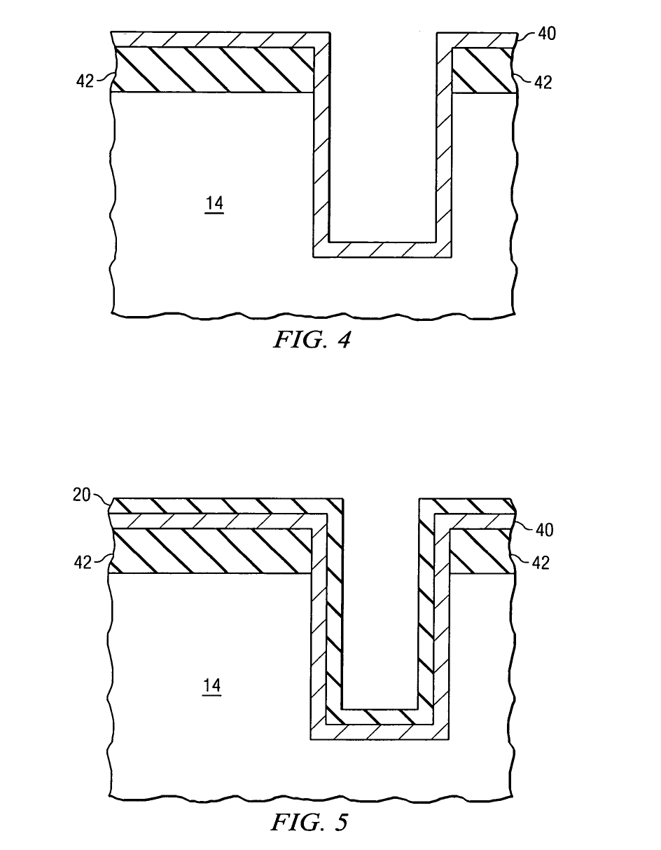

FIG. 2 illustrates an embodiment that explicitly shows a metal layer 40 that is formed between the semiconductor material of buried plate 16 and the dielectric layer 20. In the illustrated embodiment, metal layer 40 is in direct contact with silicon substrate 14. In one example, the metal layer 40 can preferably be any metal with a high affinity for oxygen and a melting point (both for the solid solution with oxygen and the oxide) above about 1000° C. In various embodiments, the metal layer 40 could comprise either flash metal (e.g., Ti) only, a flash metal with another metal electrode (e.g., TiN, TaN, Ru, or others), or only the metal electrode.

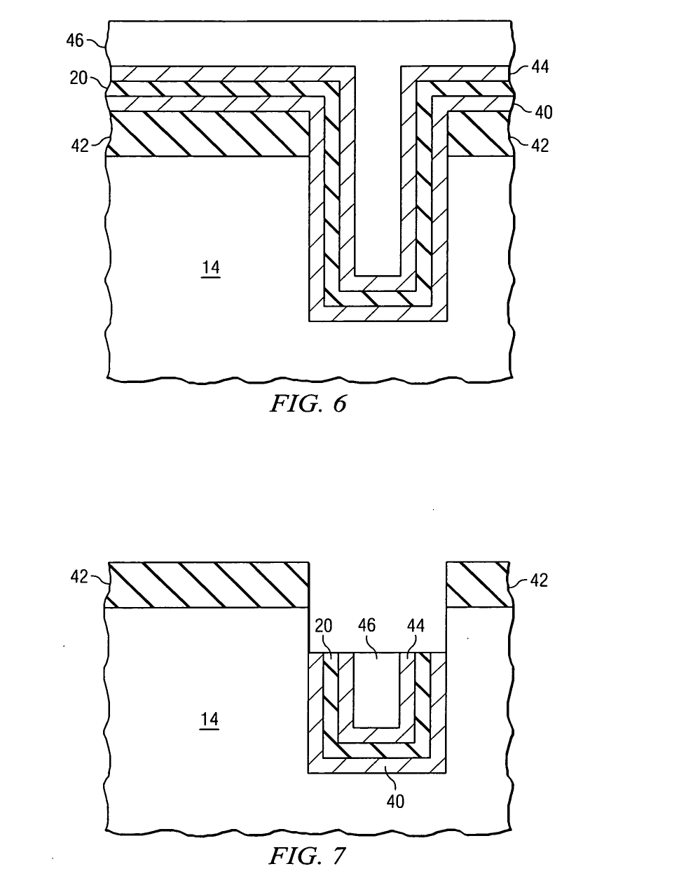

A method of forming the DRAM cell of the present invention will now be described with respect to FIGS. 3-8. Referring first to FIG. 3, a semiconductor substrate 14 is provided. The substrate 14 can be an upper portion of a bulk silicon substrate or a silicon layer over another layer. As examples, the silicon layer can be part of a silicon-on-insulator (SOI) substrate, an epitaxially grown layer over another layer (e.g., silicon over silicon germanium), or a silicon layer formed by a wafer bonding technique. The silicon layer could also be a layer formed over a substrate, e.g., a polysilicon layer used as a gate electrode or an electrode used in a stacked capacitor. Semiconductors other than silicon, e.g., germanium, silicon germanium, gallium arsenide and others, could alternatively be used.

A hard mask layer 42 is deposited over the substrate 14. The hard mask material is selected so that silicon can be etched selectively with the hard mask 42. In the preferred embodiment, the hard mask is silicon nitride (e.g., Si₃N₄). This layer is patterned using known photolithographic techniques and a trench is etched into the semiconductor body 14 in alignment with the mask 42. In the preferred embodiment, the trench is etched to a diameter of between about 35 nm and about 350 nm and a depth of about 4 μm and about 9 μm.

Referring to FIG. 4, the metal layer 40 is deposited. In a first example, the first metal layer 40 can be titanium formed to a thickness of about 1 to about 10 nm. This layer can be deposited by atomic layer deposition using a thermal process (preferably) or a suitable plasma-enhanced deposition process, e.g., Ti(OEt)₄ or TiCl₄ with a H₂ plasma. The metal layer 40 can be deposited using appropriate precursors and an atomic layer deposition (ALD) process, as an example. Plasma enhancement would facilitate reduction of the metal ligand after attachment to the substrate. An example of such a deposition process is the use of PEALD (plasma enhanced ALD) to deposit Ti. TiCl₄ is the precursor for Ti and atomic hydrogen (produced with an RF plasma) is used as the reducing agent. A suitable example of a Ti ALD is described in Kim et al., “Growth kinetics and initial stage growth during plasma-enhanced Ti atomic layer deposition,” Journal of Vacuum Science and Technology, A 20(3), May/June 2002, pp. 802-808, which paper is incorporated herein by reference.

In other embodiments, other deposition techniques could be used. For example, for deep trenches, such as those described herein, a thermal ALD process may be used to ensure adequate step coverage. Other options include thermal ALD using TiCl4, Ti-amides, or Ti-alkoxides with H₂O or O₃. In other embodiments, other methods can be used to deposit Ti, e.g., physical vapor deposition (PVD) from a Ti target, chemical vapor deposition (CVD), or molecular beam epitaxy (MBE).

Other details regarding the metal layer are provided in co-pending patent application Ser. No. 11/031,596 (2004P54458), which patent application is incorporated herein by reference.

The preferred embodiment of this invention uses an oxygen/nitrogen gettering layer 40 (sacrificial in nature since it may be partially or completely converted to a new phase) as a means of modifying the interface between the dielectric layer 20 and the substrate 14. Metals such as titanium form a solid solution with oxygen and are, therefore, very effective as gettering layers. Furthermore, formation of a silicide layer at the interface would be very useful for MIM capacitors. The segregation of oxygen can be tailored (through temperature, time, and partial pressure control) such that a pure silicide is in contact with the silicon substrate and the silicate/oxide is formed above the silicide layer.

Referring now to FIG. 5, dielectric 20 is deposited over the layer 40. A wide variety of dielectrics can be used. For example, dielectric 20 can be an oxide (e.g., silicon dioxide) or a nitride (such as silicon nitride, e.g., Si₃N₄). Combinations of oxides and nitrides can also be used. For example, dielectric 20 can be silicon oxynitride (SiON) or a composite layer such as an oxide-nitride-oxide (ONO) layer. With silicon oxide, silicon nitride, and combinations thereof, the preferred physical thickness of dielectric 20 is between about 1 nm and 10 nm, preferably about 3 nm, depending on the dielectric constant of the layer.

The process of the present invention is especially useful with high K dielectrics, such as those materials with a dielectric constant greater than about 10 in one embodiment and a dielectric constant greater than about 20 in another embodiment. Suitable examples include Hf or Al based oxides such as Al₂O₃, HfO₂, and Hf—Al—Ox. Other examples include titanium oxide (TiO₂), lanthanum oxide (e.g., La₂O₃), barium-strontium titanate (BST) ((BaSr)TiO₃ or BSTO), and strontium titanate (STO).

Co-pending application Ser. No. 11/031,716 (Docket No. 2004P54456) describes a number of high K dielectrics that are particularly useful in embodiments of the present invention. For example, that application provides a dielectric layer with K greater than 25 and adequate conduction band offset with silicon. Exemplary embodiments proposed in the co-pending application use the following material systems: HfᵤTiᵥTa_{w}OₓN_{y}, HfᵤTiᵥOₓN_{y}, TiᵤSrᵥOₓN_{y}, TiᵤAlᵥOₓN_{y} and HfᵤSrᵥOₓN_{y} (where u, v, w, x, and y are the atomic proportions of the elements in the dielectric stack).

In the preferred embodiment, the present invention utilizes material systems that can meet the dielectric constant and other properties required to achieve low leakage and high capacitance. In the preferred embodiment, these material systems are based on TiO₂, which has a dielectric constant around 80 but has a very low conduction band offset (Ec) to silicon (<1.2 eV), and low band gap (E_{g}˜3.5 eV). Candidates for combining with TiO₂ are: Ta₂O₅ (k=26, E_{c}<1.5 eV, Eg˜4.5), Al₂O₃ (k=9, Ec=2.8 eV, Eg˜8), HfO₂ (k=20, Ec=1.5 eV, Eg=5.8 eV), La₂O₃ (k=30, Ec=2.3 eV, Eg=4.3 eV), SrTiO₃ (k>100), Hf₃N₄ (k˜30), and others. Combinations of these materials are also envisioned.

In the preferred embodiment, the individual components can be deposited by atomic layer deposition (ALD). Suitable precursors will be used for deposition of the various components (oxides, nitrides) listed above. For example, HfO₂ using TEMAHf with O₃ or H₂O, Hf₃N₄ using TEMAHf with NH₃.

As shown in FIG. 5, dielectric layer 20 is formed over the substrate 14 (and metal layer 40, if included). In the preferred embodiment, the dielectric layer 20 is deposited by ALD of the individual components. Specific examples of materials are provided below. The thickness of this layer (typically, about 2 nm to about 20 nm), the thicknesses of the individual sub-layers, and the sequence of the layers is variable and depends on the capacitance enhancement to be achieved.

In a first embodiment, the dielectric layer 20 comprises a nanolaminate formed by sequential layers of a first material that has a high dielectric constant and subsequent layers that have a high band offset relative to silicon (e.g., greater than about 1.5 to 2 eV). This combination of materials is preferred since a high dielectric constant material will retain charge and a high band offset will avoid leakage. For example, as discussed above, TiO₂ has an excellent dielectric constant of around 80, but the conduction band offset is quite low. Hence TiO₂ is not preferred by itself. Rather, this material is preferably combined with some material, which helps to increase the band offset. Alternatively, the first layer can be a material with a high conduction band offset to silicon (e.g., Al₂O₃, HfO₂, and others). The subsequent layer could be the material with high dielectric constant (for example, TiO₂). This sequence can be repeated with or without the addition of additional binary films, as discussed below, until the required film thickness is attained.

For a nanolaminate dielectric layer 20, the individual layers (e.g., SrO, Al₂O₃, TiO₂, Hf₃N₄, AlN, HfO₂) are a few nm thick. In a preferred embodiment, the thickness is preferably about 0.5 nm to about 4 nm, typically about 1 nm. The layers are ideally intact as deposited. However, some intermixing/reactions can occur at the interfaces between each layer during a high temperature anneal.

In another embodiment, the dielectric 20 can be a mixed compound. In this case, thin layers are formed and then the structure is annealed to form, for example, a single compound. For mixed compounds, the individual layer thickness (as deposited) is typically less than 0.5 nm, to ensure a more homogenous film. After, a high temperature anneal, the ideal scenario is that there is no crystallization of the film and that it does not separate into a few distinct compounds (which is possible, depending on the composition of the films). The typical approach, which could be used to predict what phases will be present after an anneal is to use Quantum chemical calculations, molecular orbital theory and free energy minimization techniques. Since the exact details of the effect of an anneal on the mixed compounds is quite difficult to predict due to the fact that it may not be a completely stable, thermodynamic system, any implementation will require actual verification using a combination of techniques such as high resolution TEM, electron energy loss spectroscopy, Rutherford backscattering, X-ray photoelectron spectroscopy, or others. In any event, the present invention encompasses all phases from nanolaminate to mixed compound and in between.

In another embodiment, a method to form capacitors with low leakage and high capacitance involves a judicious mixing of oxides/nitrides/oxynitrides based on TiO₂ and perovskites such as SrTiO₃. Five exemplary systems are disclosed here. Each of these will be discussed now. These systems can be implemented as either a nanolaminate or a mixed compound.

A first system utilizes HfᵤTiᵥTa_{w}OₓN_{y}. In the preferred embodiment, 0<u<60, 0<v<60, 0<w<60, 0<x<50, and 0<y<50, and u+v+w+x+y˜100. (It is recognized that some contaminants such as Cl, C, and H may be present, depending on the deposition process. These contaminants are ignored for purposes of determining the ratio of materials in the system). This embodiment includes all possible combinations of mixed oxides, nitrides and oxynitrides. For example, a mixed oxide can be formed by depositing alternating layers of Hf₃N₄, HfO₂, TiO₂, and Ta₂O₅. This can be converted to a nanolaminate structure by increasing the thickness of the sub-layers. The composition can be tailored by varying the number of cycles of each sub-layer.

As an example, a layer of Hf₃N₄ is deposited to a thickness of between about 0.5 nm and about 3 nm, preferably about 2 nm. Next a layer of HfO₂ is deposited to a thickness of between about 0.5 nm and about 3 nm, preferably about 2 nm. A layer of TiO₂ can be deposited to a thickness of between about 0.5 nm and about 3 nm, preferably about 2 nm. Finally, a layer of Ta₂O₅ can be deposited to a thickness of between about 0.5 nm and about 3 nm, preferably about 2 nm. These four layers can be repeated between about 1 and 10 times.

The sequence of deposition and the individual layer thickness' can also be changed to modify the properties of the ensuing dielectric stack. This would be the approach for forming a nanolaminate structure. The same group of binary mixtures can be processed in the form of mixed oxynitrides by reducing the layer thickness to 1 nm or less (preferably closer to a monolayer or about 0.5 nm thick). Another variation is to only use a subset of these binary mixtures. For example, HfO₂ and TiO₂ can be used to develop a HfᵤTiᵥOₓ (which is the result of setting w and y equal to 0 in HfᵤTiᵥTa_{w}OₓN_{y}).

A second example utilizes a HfᵤTiᵥOₓN_{y} system, including all possible combinations of mixed oxides, nitrides and oxynitrides. In the preferred embodiment, 0<u<60, 0<v<60, 0<x<50, and 0<y<50, and u+v+x+y˜100 (some contaminants such as Cl, C, and H may be present, depending on the deposition process). For example, a mixed oxide can be formed by depositing alternating layers of Hf₃N₄, HfO₂, and TiO₂. This can be converted to a nanolaminate structure by increasing the thickness of the sub-layers. For example, a nanolaminate of TiO₂ and HfO₂ can be formed. Nitrogen can be incorporated in this structure by using an appropriate nitriding anneal (e.g., in a forming gas, NH₃ atmosphere, or N₂ atmosphere). The composition can be tailored by varying the number of cycles of each sub-layer.

Another option is to deposit HfO₂, TiO₂ and Ti layers. (This is an example where y is set equal to 0 in HfᵤTiᵥOₓN_{y}.) The Ti content of the stack can then be independently controlled. The gettering effect of Ti can be used to control the oxygen content of the various oxides. For example, a first layer of Ti (e.g., 0.3 to 1 nm thick) can be deposited. This could be followed by an HfO₂ layer (0.3 to 1 nm thick). Another Ti layer can be deposited (e.g., 0.3 to 1 nm thick). A layer of TiO₂ can be deposited next (e.g., 0.3 to 1 nm thick). This sequence can be repeated to get a Ti-rich structure. Thicker layers of the binary mixtures (1 nm or greater) can be used to form nanolaminate structures. To reduce the Ti content, the Ti layer between HfO₂ and TiO₂ could be eliminated, for example. Alternatively, the relative thickness of the Ti layer can be increased with respect to the thickness of the HfO₂ or TiO₂ layers.

Another system utilizes TiᵤSrᵥOₓN_{y} and includes all possible combinations of mixed oxides, nitrides and oxynitrides. In the preferred embodiment, 0<u<60, 0<v<60, 0<x<50, and 0<y<50, and u+v+x+y˜100 (some contaminants such as Cl, C, and H may be present, depending on the deposition process). For example, a mixed oxide can be formed by depositing alternating layers of SrO, Sr₃N₂ and TiO₂. This can be converted to a nanolaminate structure by increasing the thickness of the sub-layers. The composition can be tailored by varying the number of cycles of each sub-layer.

In the Atomic Layer Deposition (ALD) process, compound films are deposited by alternating the introduction of a precursor (e.g., TiCl₄, a possible source for Ti), purging the process chamber with an inert gas (say argon), introduction of the precursor/reactant containing the remaining component for the compound film (e.g., NH₃, a possible source for N), followed by a purge with inert gas (say argon) so as to evacuate the chamber. This consists of one ALD cycle. If the process parameters are optimized, ALD results in self-limiting growth, with the final thickness being a function of the number of ALD cycles. ALD can be used to generate nanolaminate or mixed oxynitrides by varying the sequence and number of cycles for the different binary mixtures, which are used to deposit the dielectric film. For example, one ALD cycle each of SrO, Sr₃N₂ and TiO₂ can be repeated until the desired thickness is attained. Alternatively, two cycles of SrO can be followed by three cycles of Sr₃N₂ and one cycle of TiO₂. Extending this approach, a variety of compositions can be formed and different settings for u, v, x and y generated.

Suitable precursors will be used for deposition of the various components (oxides, nitrides) listed above. For example, the possible sources for:
a. Oxygen are H₂, O₂ or O₃
b. Nitrogen are NH₃, N₂
c. Hafnium are metal alkyl amides (e.g., Tert ethyl methyl amino hafnium), metal halides (e.g., HfCl₂), metal alkoxides.
d. Titanium are metal halides (e.g., TiCl₄), metallorganics (e.g., TDMAT), metal alkoxides (e.g., Ti(OEt)₄).
e. Aluminum are metal alkyl amides (e.g., trimethyl aluminum), metal alkoxides.
f. Tantalum are metal alkyl amides (e.g., terbutylimidotris diethylamido tantalum or TBTDET), metallorganics, metal alkoxides.
g. Ruthenium are metal cyclopentadienlyls (e.g., Ru(Cp)₂— biscyclopentadienyl ruthenium, Ru(ethylCp)₂).
h. Strontium are metal cyclopentadienyls, metal alkyl amides, metal beta-diketonates, metal alkoxides.

Another approach would be to form a mixed oxide, e.g., by varying layers of TiO₂ and SrO. Once the TiₓSrᵤOₓ oxide is formed, nitrogen can be incorporated in this structure by using an appropriate nitriding anneal (e.g., in a forming gas, NH₃ atmosphere, or N₂ atmosphere). In the illustrated example, this anneal would be performed after deposition of the mixed oxide film deposition. An RTP anneal would be a preferred method, at temperatures between about 400° C. and 1000° C., for up to 60 seconds. Nitridation can also be achieved by using a furnace at temperatures between about 500° C. and 1100° C., for 5 to 30 minutes.

The RTP can cause metal layer 40 to react with the substrate 14. For example, if the metal is a refractory metal such as titanium, the removal of the silicide could be challenging. To remove the material, a dry or wet etch that has a high selectivity with respect to the silicide will have to be performed if it is desirable to remove the metal, as in the case of the trench capacitor. In the case of a stack capacitor (discussed in more detail below), the excess metal would not need to be removed.

Another option for dielectric 20 is to deposit SrO, TiO₂ and Ti layers. The Ti content of the stack can then be independently controlled. The gettering effect of Ti can be used to control the oxygen content of the various oxides. The approach here is similar to that described above. For example, if ALD is used, one ALD cycle each of SrO, Ti and TiO₂ can be repeated until the desired thickness is attained. Alternatively, two cycles of SrO can be followed by three cycles of Ti and one cycle of TiO₂. Extending this approach, a variety of compositions can be formed and different settings for u, v, x and y generated.

Yet another system utilizes TiᵤAlᵥOₓN_{y}, including all possible combinations of mixed oxides, nitrides and oxynitrides. In the preferred embodiment, 0<u<60, 0<v<60, 0<x<50, and 0<y<50, and u+v+x+y˜100 (some contaminants such as Cl, C, and H may be present, depending on the deposition process). For example, a mixed oxide can be formed by depositing alternating layers of Al₂O₃, AlN, and TiO₂. This can be converted to a nanolaminate structure by increasing the thickness of the sub-layers. The ALD approach described above would once again apply to this embodiment.

Another approach would be to form a mixed oxide, e.g., by varying layers of TiO₂ and Al₂O₃. Once the TiₓAlᵤOₓ oxide is formed, nitrogen can be incorporated in this structure by using an appropriate nitriding anneal (e.g., in a forming gas, NH₃ atmosphere, or N₂ atmosphere). This anneal would be performed after completion of the mixed-oxide film deposition. An RTP anneal would be a preferred method, at temperatures between about 400° C. and 1000° C., for up to about 60 seconds. Nitridation can also be achieved by using a furnace at temperatures between about 500° C. and 1100° C., for about 5 to 30 minutes. As discussed above, any recipe that utilizes an RTP anneal at this step in the process flow is better suited for a stack capacitor.

The final embodiment described here presents an HfᵤSrᵥOₓN_{y} system, including all possible combinations of mixed oxides, nitrides and oxynitrides. In the preferred embodiment, 0<u<60, 0<v<60, 0<x<50, and 0<y<50, and u+v+x+y˜100 (some contaminants such as Cl, C, and H may be present, depending on the deposition process). For example, a mixed oxide can be formed by depositing alternating layers of HfO₂, SrO, Sr₃N₂, and/or Hf₃N₄. This can be converted to a nanolaminate structure by increasing the thickness of the sub-layers. The ALD approach described above can once again be utilized.

Another approach would be to form a mixed oxide, e.g., by varying layers of HfO₂ and SrO. Once the HfₓSrᵤOₓ oxide is formed, nitrogen can be incorporated in this structure by using an appropriate nitriding anneal (e.g., in a forming gas, NH₃ atmosphere, or N₂ atmosphere). This anneal would be performed after completion of the mixed-oxide film deposition. An RTP anneal would be a preferred method, at temperatures between about 400° C. and 1000° C., for up to about 60 seconds. Nitridation can also be achieved by using a furnace at temperatures between about 500° C. and 1100° C., for about 5 to 30 minutes.

After an adequate film thickness of dielectric is deposited, the wafer can be sent on for deposition of a top metal electrode 44. FIG. 6 illustrates an embodiment where the storage node electrode 18 (as labeled in FIG. 2) is implemented with a metal layer 44 and a fill conductor 46. The metal layer 44 could be formed from either pure metal (e.g., Ru, Hf, Ti, Ta, others), nitrides (e.g., TiN, TaN, HfN, mixtures of these) or carbo-nitrides (e.g., TiCN, NbCN, HfCN, TaCN). For example, TiN could be deposited by ALD using TiCl₄ and NH₃.

In the preferred embodiment, the fill conductor 46 is polysilicon. This layer is optional. For example the trench could be filled only with the metal of metal layer 44. Alternatively, the metal layer 44 can be eliminated and the trench can be filled only with polysilicon.

In one embodiment (which is not illustrated), a metal flash layer such as that used for layer 40 is formed over the dielectric 20. If a layer of that material is used above the dielectric 20, then in some embodiments the layer could be eliminated. If the dielectric layer 20 is thin enough, e.g., 2 to 10 nm thick, the interface between the dielectric layer 20 and substrate 14 can be cleaned up by a metal flash in this location. The thickness of the dielectric could be around 1 to 3 nm. An optional anneal step could follow the metal flash layer deposition. The anneal would be between about 400° C. to 1100° C. for about 10 to 60 seconds and RTP at about 400° C. to 1000° C. for about 5 to 30 minutes for an anneal. The anneal could be controlled so as to form either a TiOx solid solution or an oxide of Ti (e.g., TiO₂). As with the layer 20, this additional (alternate) metal layer could comprise either flash metal (e.g., Ti) only, a flash metal with another metal electrode (e.g. TiN, TaN, Ru, or others), or only the metal electrode.

Referring now to FIG. 7, the capacitor materials 40, 20, 44, and 46 are etched back within the trench. At this point, the structure can be subjected to an anneal. This anneal will serve to cause the appropriate reactions at the dielectric 20 interface. In the case of a mixed compound dielectric, the appropriate layers will also be integrated together. Preferably, the anneal is performed using a rapid thermal process (RTP) with a controlled atmosphere. Alternatively, a controlled furnace anneal could be utilized. In the RTP example, the structure can be heated to a temperature between about 400° C. and about 1100° C. for a time of about 10 to about 60 seconds. In the furnace anneal example, the structure can be heated to a temperature between about 400° C. and about 1000° C. for a time of about 5 to about 30 minutes.

Referring now to FIG. 8, the trench structure is completed. In this process, the oxide collar 32 is formed by thermal oxidation of exposed portions of the trench sidewalls. The trench can then be filled with a conductor such as polysilicon 48. Both the polysilicon 48 and oxide collar 32 are then etched back to expose a sidewall portion 50 of the substrate 14. This sidewall portion 50 will form the interface between the access transistor 28 and capacitor 12.

After collar 32 is etched back, the buried strap 30 is completed by deposition of a conductive material, such as doped polysilicon. In the preferred embodiment, the polysilicon regions 30, 48 and 46 are all doped with arsenic, although it is understood that other dopants (e.g., phosphorus) could be used. Further, any or all of the materials for regions 30, 48 and 46 can be a conductive material other than polysilicon (e.g., a metal).

The strap material 30 and semiconductor body 14 can then be patterned and etched to form the STI regions. The STI regions 36 can be filled with an insulator such as an oxide deposited by a high density plasma process (i.e., HDP oxide). Appropriate liners could be included.

The transistor 28 can then be formed to create the structure shown in FIGS. 1 (and 2). Other process steps such as dielectric formation and metallization are not described herein for purposes of simplicity. It is also understood that the process steps described herein are exemplary and any number of variations could be incorporated without departing from the spirit of the invention.

For example, FIGS. 1 and 2 illustrate a planar transistor 28. The present invention envisions use of the novel capacitor 12 with a vertical transistor that includes a gate 26 formed within the trench and source, drain and channel regions 22, 24, 34 formed along a sidewall of the trench.

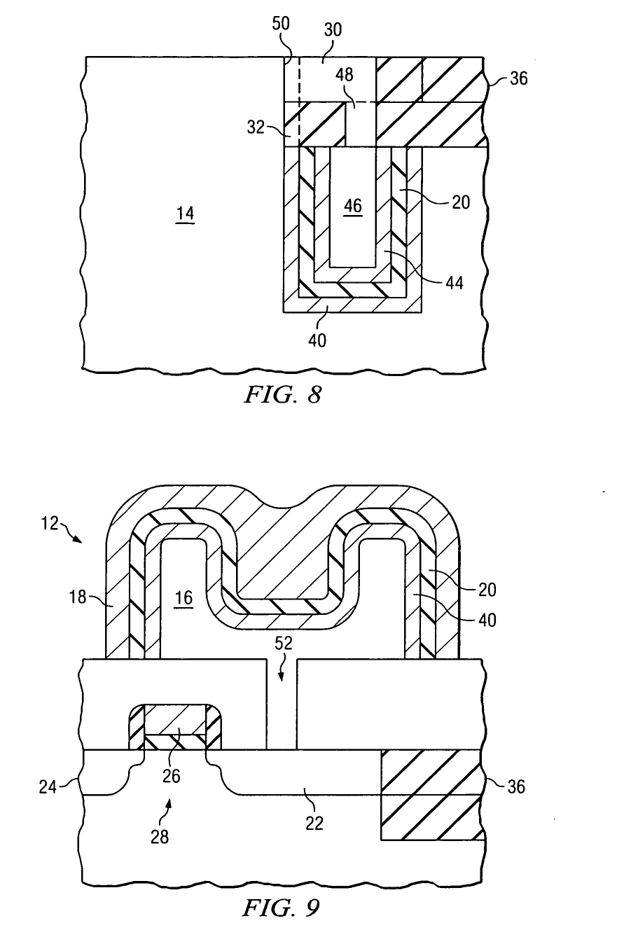

FIG. 9 shows yet another example of a DRAM cell that can utilize inventive aspects of the present invention. In this case, the capacitor 12 is a stacked capacitor (since both plates are above the substrate). The stack capacitor includes a first electrode 16, which is preferably formed from polysilicon. This electrode 16 is electrically coupled to transistor 28 source/drain region 24, e.g., through a via 52. Via 52 can be formed from the same material or a different material as capacitor electrode 16.

In the preferred embodiment, metal layer 40 is formed over the electrode 16. This layer can be formed by any of the processes described herein or in the co-pending application Ser. No. 11/031,596 (2004P54458). For example, a layer 40 of titanium can be deposited by atomic layer deposition. This layer can be annealed either before or after forming a dielectric layer.

Dielectric layer 20 is deposited over the capacitor electrode 16 (and metal 40, if present). Once again, dielectric layer 20 is preferably a high K dielectric such as those described above and in co-pending application Ser. No. 11/031,716 (2004P54456). As with the trench capacitor example, the high K dielectric 20 can be either a nanolaminate or a mixed compound.

Capacitor electrode 18 overlies the dielectric 20. As discussed above, the capacitor electrode 18 can be formed from polysilicon. Alternatively, or in addition, the electrode 18 can be a metal as disclosed above. The capacitor electrode 18 is typically electrically coupled to similar electrodes in other memory cells throughout the array.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of fabricating a memory cell, the method comprising:
providing a silicon body;
forming a first capacitor electrode, the first capacitor electrode comprising silicon;
forming a metal layer in physical contact with the first capacitor electrode, the metal layer being formed from a material having a high affinity for oxygen and a melting point above about 1000° C.;
forming a layer of high K dielectric material in physical contact with the metal layer, the high K dielectric material having a dielectric constant greater than about 5;
forming a conductive layer over the high K dielectric material layer;
modifying an interface between the high K dielectric layer and the metal layer/silicon body by performing an annealing step; and
forming a transistor within the silicon body, the transistor being electrically coupled to one of the conductive layer or the first capacitor electrode.

2. The method of claim 1 and further comprising forming a compound metal layer in contact with the first metal layer.

3. The method of claim 1 wherein the memory cell comprises a trench DRAM cell, wherein the transistor is electrically coupled to the first capacitor electrode, wherein forming a first capacitor electrode comprises forming a trench within the silicon body, and wherein forming a metal layer comprises depositing the metal layer along sidewalls of the trench.

4. The method of claim 1 wherein the memory cell comprises a stacked capacitor DRAM cell, wherein the transistor is electrically coupled to the conductive layer and wherein forming a first capacitor electrode comprises depositing polysilicon above the silicon body.

5. The method of claim 1 wherein the metal layer comprises a titanium layer.

6. The method of claim 5 wherein the modifying step comprises forming titanium silicide.

7. The method of claim 5 wherein the modifying step comprises forming titanium oxide.

8. The method of claim 5 wherein the high K dielectric comprises a material selected from the group consisting of HfᵤTiᵥTa_{w}OₓN_{y}, HfᵤTiᵥOₓN_{y}, TiᵤSrᵥOₓN_{y}, TiᵤAlᵥOₓN_{y} and HfᵤSrᵥOₓN_{y}, where u, v, w, x, and y are the atomic proportions of the elements in the dielectric material.

9. A method of forming a semiconductor device, the method comprising:
providing a semiconductor body;
etching a trench in the semiconductor body;
lining sidewalls of the trench with a metal layer;
depositing a dielectric layer over the metal layer, the dielectric layer having a dielectric constant greater than 5;
depositing a conductor to fill the trench;
etching back the metal layer, the dielectric layer and the conductor; and
performing an anneal to modify an interface between the dielectric layer and the semiconductor.

10. The method of claim 9 and further comprising forming a transistor in the semiconductor body, the transistor electrically coupled to the conductor.

11. The method of claim 9 wherein depositing a metal layer comprises depositing titanium.

12. The method of claim 11 wherein modifying the interface comprises forming titanium silicide.

13. The method of claim 12 wherein depositing a dielectric layer comprises depositing a dielectric formed from at least one material selected from the group consisting of HfᵤTiᵥTa_{w}OₓN_{y}, HfᵤTiᵥOₓN_{y}, TiᵤSrᵥOₓN_{y}, TiᵤAlᵥOₓN_{y} and HfᵤSrᵥOₓN_{y}, where u, v, w, x, and y are the atomic proportions of the elements in the dielectric material.

14. The method of claim 13 wherein depositing a dielectric layer comprises depositing a nanolaminate.

15. The method of claim 9 wherein depositing dielectric layer comprises depositing a mixed oxynitride layer.

16. The method of claim 9, wherein modifying the interface comprises forming a silicide.

17. The method of claim 9 wherein depositing a dielectric layer comprises depositing a dielectric formed from at least one material selected from the group consisting of HfᵤTiᵥTa_{w}OₓN_{y}, HfᵤTiᵥOₓN_{y}, TiᵤSrᵥOₓN_{y}, TiᵤAlᵥOₓN_{y} and HfᵤSrᵥOₓN_{y} where u, v, w, x, and y are the atomic proportions of the elements in the dielectric material.

18. The method of claim 9, wherein depositing a dielectric layer comprises depositing a layer that includes hafnium.
